(19) United States
(12) Patent Application Publication
(10) Pub. No.: US 2003/0112159 A1
(43) Pub. Date: Jun. 19, 2003

(54) External input unit with ten-key pad connectable to computer main unit

(75) Inventors: Kazutoshi Watanabe, Fukushima-ken (JP); Masahiro Soma, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/309,496

(22) Filed: Dec. 4, 2002

(30) Foreign Application Priority Data
Dec. 13, 2001 (JP) 2001-379454

(51) Int. Cl. H03M 11/00; H03K 17/94

(52) U.S. Cl. 341/22

(57) ABSTRACT

A casing includes a first ten-key input section and a second ten-key input section independently. The first ten-key input section has ten-keys and the second ten-key input section has cursor keys. Thus, even during normal Japanese entry, the entry operations of the ten-keys and the cursor keys are possible in parallel and operability is not reduced.

### BACKGROUND OF THE INVENTION

1. Field of the Invention

The present invention relates to an external input unit connectable to a computer main unit such as a laptop computer, and more particularly, concerns an external input unit having a ten-key pad and other peripherals integrated with each other.

2. Description of the Related Art

Personal computers have a keyboard unit; however, laptop computers have a structure in which a keyboard unit is integrated with the main unit, thus having a limited placement space for the keyboard unit. Therefore, the number of keys that can be arranged on the keyboard unit is also limited. Because of this limitation, the keyboard units of the laptop computers have not an input section exclusive for a ten-key pad, and ten-key input keys are generally assigned to symbol keys and character keys of the keyboard unit.

The keyboard unit has a number lock (Num Lock) key, wherein by operating the [Num Lock] key, Japanese entry using character keys and numeric entry can be switched.

FIG. 8 is a plan view of an example of a keyboard unit mounted to a laptop computer, showing a part of the keyboard layout.

A keyboard unit 100 of this example includes a key input section 101 having character keys and symbol keys. A group of keys 102 forming a part of the key input section 101 is used both as character keys or symbol keys and ten-keys. When a [Num Lock] key 103 provided on the keyboard unit 100 is pressed to switch to a lock mode, the keys 102 can be used as ten-keys, thus allowing the entry of numeric. When the [Num Lock] key 103 provided is in an unlock mode, the keys 102 can be used as character keys or symbol keys, thus allowing the entry of Japanese using the keys of the key input section 101 and the keys 102.

As described above, the keyboard unit 100 mounted to a laptop computer involves pressing the [Num Lock] key 103 for numeric entry. Therefore, for example, when numeric is entered or numeric calculation is recorded while entering Japanese character with word processing software, the [Num Lock] key must be switched as occasion arises; thus, it is extremely inconvenient.

The keys 102 provided on the keyboard unit 100 have laterally alternate key layout in each array, thus having a drawback in that it is difficult to operate in numeric entry or calculation.

There is also provided an external input unit having a keyboard, which is connectable to the laptop computer. In this conventional external input unit, ten-keys and cursor keys share the same keys, and ten-keys and symbol keys share the same keys. Therefore, the external input unit also needs the [Num Lock] key, wherein when the same keys are used both as the cursor keys and character keys and when the same keys are used as numeric keys, the [Num Lock] key must be operated; thus the operation is troublesome.

The [Num Lock] key provided on the keyboard unit of the computer main unit and the external input unit are in conjunction with each other when the external input unit is connected to the main unit. Therefore, when the [Num Lock] key of the main unit is operated, the input item of the external input unit is also switched.

Accordingly, even when the external input unit is connected, the [Num Lock] key must be operated when numeric is entered during the entry of Japanese; thus, the operation is troublesome.

Since the main unit of the laptop computer is limited in size, the main unit cannot have a large number of input units. Thus, a mouse, a pointing device, a printer, a communication device and so on are connected to the main body with a cable in many cases.

However, when various types of external input units are connected to the laptop computer, they occupy the periphery of the computer, thus obstructing effective use of space. Also, when the mounting space is limited, all necessary external input units cannot be mounted.

### SUMMARY OF THE INVENTION

The present invention has been made to solve the conventional-art problems. Accordingly, it is an object of the present invention to provide an external input unit capable of various inputs in limited space and facilitating ten-key entry operation.

According to a first aspect of the present invention, there is provided an external input unit with a ten-key pad connectable to a computer main unit having an integrated or separate key input section, wherein a casing separate from the computer main unit includes at least ten-key and cursor key arrangement; and a circuit in the casing and the computer main unit are connected through a single interface circuit.

Since numeric entry with the ten-keys and cursor moving operation with the cursor keys can be performed in parallel using the external input unit, numerics can be entered with the ten-keys provided to the external input unit at all times and also cursors can be moved at all times. Therefore, numeric entry and cursor movement can quickly be performed using the external input unit during Japanese entry with the keyboard of the computer main unit, thus facilitating entry operation.

The casing may include no character entry keys and symbol entry keys or, may have a minimum of symbol keys in addition to the ten-keys and the cursor keys.

According to a second aspect of the present invention, there is provided an external input unit with a ten-key pad connectable to a computer main unit having an integrated or separate key input section, wherein a casing separate from the computer main unit includes at least ten-key arrangement; and the casing further includes a recording-medium drive unit to which a recording medium is mounted; and a circuit in the casing and the computer main unit are connected through a single interface circuit.

According to a third aspect of the present invention, there is provided an external input unit with a ten-key pad connectable to a computer main unit having an integrated or separate key input section, wherein a casing separate from the computer main unit includes at least ten-key arrangement; the casing further includes a connector capable of communicating with another external input unit or portable terminal; and a circuit in the casing and the computer main unit are connected through a single interface circuit.

According to a fourth aspect of the present invention, there is provided an external input unit with a ten-key pad connectable to a computer main unit having an integrated or separate key input section, wherein a casing separate from the computer main unit includes at least ten-keys and a coordinate entry means; and a circuit in the casing and the computer main unit are connected through a single interface circuit.

According to the second to fourth aspects of the present invention, the external input unit is allowed to perform not only the key entry but also reading of a recording medium, relay to other external input units, and coordinate entry, thereby allowing the single unit to be used for various uses; and a minimum of space around the computer main unit such as a laptop computer can be effectively used.

In the foregoing invention, the casing may include a display panel; the casing may integrally or detachably include a camera capable of digital input; and the casing may integrally include an output unit having a print function.

The invention of the first to fourth aspects may be combined, and the display panel, the camera, and the output unit may be combined as required.

In the foregoing, the casing of the external input unit may include no [Num Lock] key, and the numeric entry with the ten-key pad provided to the casing and the character or symbol entry with the key input section of the computer main unit may be performed in parallel. In other words, the numeric entry and the cursor movement operation may be performed at all times with the keys provided to the casing of the external input unit, irrespective of the [Num Lock] key operation of the main unit.

### BRIEF DESCRIPTION OF THE DRAWINGS

FIG. 1 is a perspective view of an external input unit according to a first embodiment of the present invention;

FIG. 2 is a block diagram of the external input unit according to the first embodiment;

FIG. 3 is a perspective view of an external input unit according to a second embodiment of the present invention;

FIG. 4 is a block diagram of the external input unit according to the second embodiment;

FIG. 5 is a perspective view of an external input unit according to a third embodiment according to the present invention;

FIG. 6 is a block diagram of the external input unit according to the third embodiment;

FIG. 7 is a perspective view of an external input unit according to a fourth embodiment of the present invention; and

FIG. 8 is an explanatory view of the input operation of a ten-key pad of a laptop keyboard unit.

### DESCRIPTION OF THE PREFERRED EMBODIMENTS

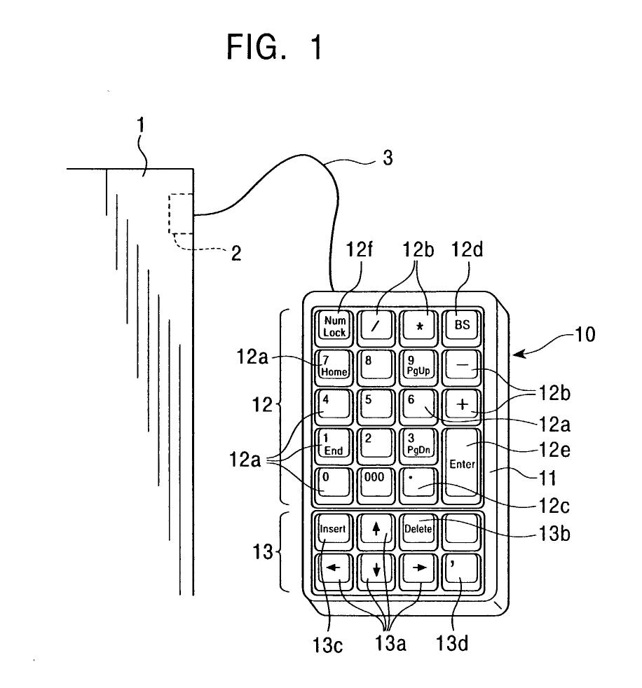

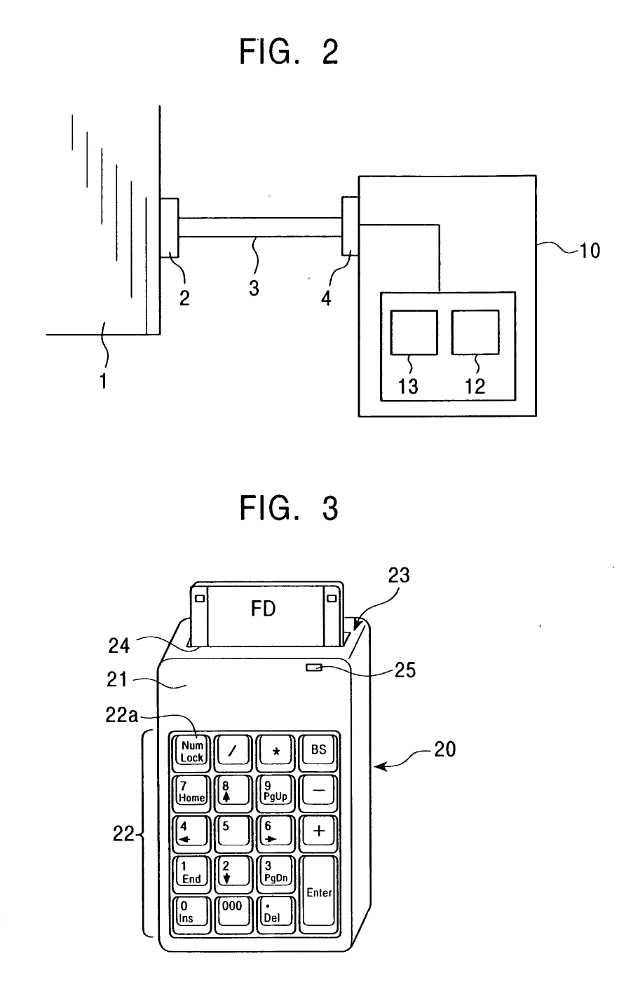

FIG. 1 is a perspective view of an external input unit 10 according to a first embodiment of the present invention; and FIG. 2 is a block diagram of the external input unit 10 according to the first embodiment.

The external input unit 10 shown in FIG. 1 is partly used for ten-key entry. The external input unit 10 is connected to a laptop computer main unit 1 or the like with a specified cable 3 via a USB (Universal Serial Bus) interface serving as a communication-medium.

The external input unit 10 has a casing 11, and a first ten-key input section 12 mainly composed of ten-keys and a second ten-key input section 13 mainly composed of cursor keys on the surface of the casing 11. The second ten-key input section 13 is placed near an operator from the first ten-key input section 12. However, the first ten-key input section 12 and second ten-key input section 13 may be arranged in reverse.

The first ten-key input section 12 of the external input unit 10 includes eleven ten-keys 12a “000, and 0 to 9” four operation keys “+, −, /, *”, a decimal point key 12c “.”, a [BS (back space)] key 12d, an [Enter key] 12e, and a [Num Lock] key 12f, having 19 keys in total. The ten-keys 12a “1, 3, 7, and 9” of the first ten-key input section 12 are assigned an [End] key, a [PgDn (page down)] key, a [Home] key, and a [PgUp (page up)] key, respectively.

The second ten-key input section 13 includes cursor keys 13a that function as direction indicator keys for moving a cursor on the screen vertically and horizontally, control keys including a [Delete] key 13b, an [Insert] key 13c, and a “'” (comma) key 13. However, the second ten-key input section 13 may be composed of only the control keys. FIG. 1 illustrates a key that is assigned no functions; however, this key may be assigned another control key or a symbol key. Other control keys may include a [Tab] key, and a [Shift] key, [F1] to [F12] (function) keys. Other symbol keys may be selected from “( )” (round brackets) keys, a “=” (equal) key, and a “@” (at mark) key.

Referring to FIG. 2, a USB port 4 of the external input unit 10 and a USB port 2 of the computer main unit 1 are connected with a specified cable 3. The cable 3 includes a data line for transmitting data and a power-supply line for supplying power. When the external input unit 10 is connected to the computer main unit 1, power is supplied from the computer main unit 1. Furthermore, when the external input unit 10 is connected to the computer main unit 1, the computer main unit 1 recognizes that the external input unit 10 has been connected, and regularly transmits signals to the external input unit 10.

When the external input unit 10 receives the signals, the first ten-key input section 12 or the second ten-key input section 13 transmits an operation signal to the computer main unit 1. At that time, an operation signal inputted at the first ten-key input section 12 is also transmitted to the computer main unit 1 over the data line of the same interface circuit.

The external input unit is allowed to perform continuous numeric entry, equation entry, and calculation processing with the keys 12a to 12e by pressing the [Num Lock] key 12f into on state. For example, when a spreadsheet application is used, numerics and equations can be quickly inputted to respective cells. On the other hand, turning the [Num Lock] key 12f off allows the operation of the control keys including the [End] keys assigned to the ten-keys 12a “1, 3, 7, and 9”.

Referring again to FIG. 1, when the second ten-key input section 13 is provided separately from and in parallel to the first ten-key input section 12, even if an erroneous character is entered, characters following the cursor can be deleted by moving the cursor to a directly preceding character of a character to be deleted and by pressing the [Delete] key 13b without pressing and switching the [Num Lock] key 12f. Also, an already inputted numeric can be overwritten by pressing the [Insert] key 13c without the switching operation with the [Num Lock] key 12f. Also for moving the cursor position, the cursor can quickly be moved to a desired position by pressing the cursor keys 13a without switching the [Num Lock] key 12f.

The conventional external input unit must perform an input operation by pressing the [Num Lock] key 12f to switch them as required; however, the external input unit 10 of this embodiment is allowed to perform the input without the switching operation; thus the operability is improved.

The external input unit 10 may not have the [Num Lock] key 12f by not assigning the [End], [PgDn], [Home], and [PgUp] keys to the ten-keys 12a “1, 3, 7, and 9” so that only one operation signal is outputted from one key. By making the operation signal outputted from the external input unit 10 identical to the operation signal outputted from the keyboard unit of the computer main unit 1, driver software for the keyboard unit, which is held in the OS (operating system) of the computer main unit 1, can be used, thus eliminating the need for installing new driver software for controlling the external input unit 10 into the computer main unit 1. Consequently, the [Num Lock] key 12f can be replaced with another character key and control key.

Also, driver software compliant with the external input unit 10 may be assembled in the computer main unit 1, wherein the computer main unit 1 and the external input unit 10 are not synchronized with each other so that the [Num Lock] key 12f of the external input unit 10 and a [Num Lock] key of the computer main unit 1 are not turned on synchronously when the [Num Lock] key 12f of the external input unit 10 is turned on. However, on the other hand, the external input unit 10 may not have the [Num Lock] key 12f, wherein when the [Num Lock] key of the computer main unit 1 is operated, the external input unit 10 does not come in Num-Lock mode, thus allowing numeric entry and cursor-movement entry from the external input unit 10 at all times.

With the aforesaid external input unit 10, when round bracket keys and an equal key are entered at the key entry section of the computer main unit 1, the operation must be made while pressing another key such as a [Shift] key. Also, the round bracket keys can be entered only after the [Num Lock] key of the keyboard unit is cancelled to allow a normal Japanese entry. However, providing the second ten-key input section 13 with round bracket keys and an equal key facilitates the entry operation for an equation using the keys.

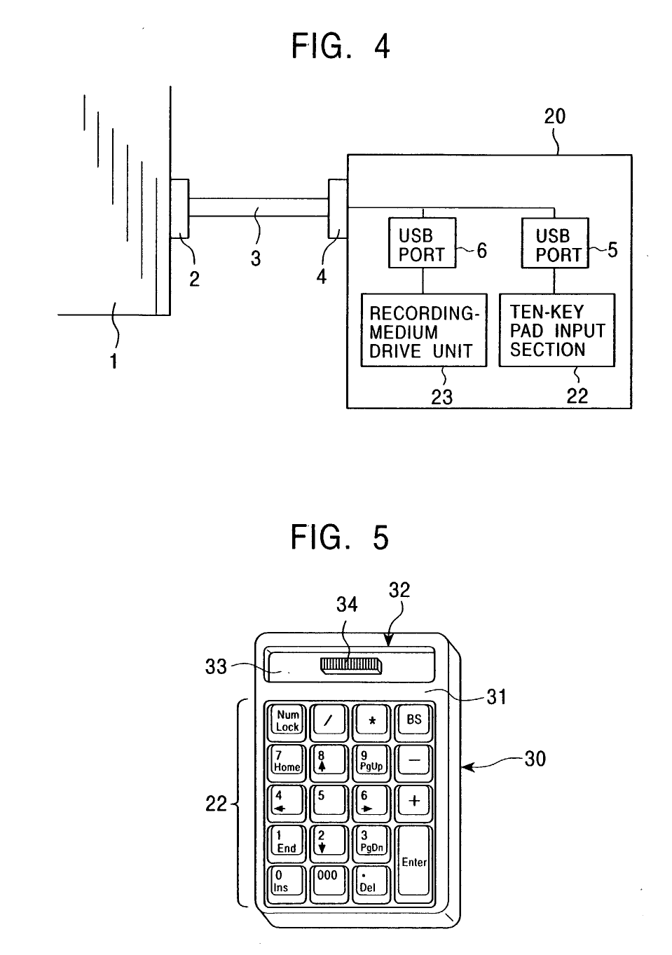

FIG. 3 is a perspective view of an external input unit 20 according to a second embodiment of the present invention; and FIG. 4 is a block diagram thereof. The external input unit 20 has a box-shaped casing 21 and a third ten-key input section 22 on the top of the casing 21. The third ten-key input section 22 has the same key layout as the first ten-key input section 12 except that upper, lower, left, and right cursor keys are assigned to the ten-keys 2, 4, 6, and 8, respectively. Accordingly, in the external input unit 20 shown in FIG. 3, ten-key entry operation with ten-keys or operation keys is allowed by pressing a [Num Lock] key 22a into on state, and control-key entry operation with cursor keys or a [Delete] key is allowed by turning the [Num Lock] key 22a into off state.

The external input unit 20 has a recording-medium drive unit 23 under the third ten-key input section 22 in the casing 21. The recording-medium drive unit 23 is a disk unit capable of recording and reproducing of a floppy disk (FD), having a slit opening 24 in the side of the casing 21, through which a FD can be let in and out. Also, a lamp 25 that generates light with an LED (light emitting diode) during recoding and reproducing the FD is provided on the top of the casing 21. Also, an eject button (not shown) for ejecting the FD is provided on the casing 21.

Referring to FIG. 4, the external input unit 20 is connected to the computer main unit 1 through the cable 3 compliant with USB interface. The external input unit 20 has therein two-split USB ports 5 and 6 connected to the USB port 4, the USB ports 5 and 6 having the third ten-key input section 22 and the recording-medium drive unit 23 connected thereto, respectively. However, the USB ports 5 and 6 may not be detachable as in the USB ports 2 and 4, and are not particularly limited as long as they function as USB ports.

Upon connection with the external input unit 20, the computer main unit 1 recognizes that the third ten-key input section 22 and the recording-medium drive unit 23 are connected with each other. At the same time, power supply from the computer main unit 1 to the external input unit 20 starts. In the computer main unit 1, upon connection with the external input unit 20, predetermined signals are periodically transmitted to the third ten-key input section 22 and the recording-medium drive unit 23. Upon receiving the signals, when an operating signal generates at the third ten-key input section 22, the operating signal is transmitted to the computer main unit 1 over the data line, and when record and reproduction processing signals generate at the recording-medium drive unit 23, the signals are transmitted to the computer main unit 1 through the same interface circuit. Accordingly, the third ten-key input section 22 and the recording-medium drive unit 23 can be simultaneously used.

Thus, since there is no need to connect the external input unit having the third ten-key input section 22 and the external input unit having the recording-medium drive unit 23 to respective USB ports for usage, the mounting space can be used effectively.

The recording-medium drive unit 23 for a FD was illustrated; however, it is not limited to that but the recording medium may be a memory card having a semiconductor element or an audio MD (mini-disc).

FIG. 5 is a perspective view of an external input unit 30 according to a third embodiment of the present invention. The external input unit 30 has the same arrangement as the external input unit 20 except units provided together with the third ten-key input section 22 of the external input unit 30. Ditto with an external input unit 40 of a fourth embodiment.

The external input unit 30 shown in FIG. 5 has a connector 32 for connecting to a mobile telephone together with the third ten-key input section 22 in a casing 31. The connector 32 has a recessed area 33 for a mobile telephone on the top of the casing 31, in which a connector 34 for connecting with an externally connecting terminal of the mobile telephone is provided.

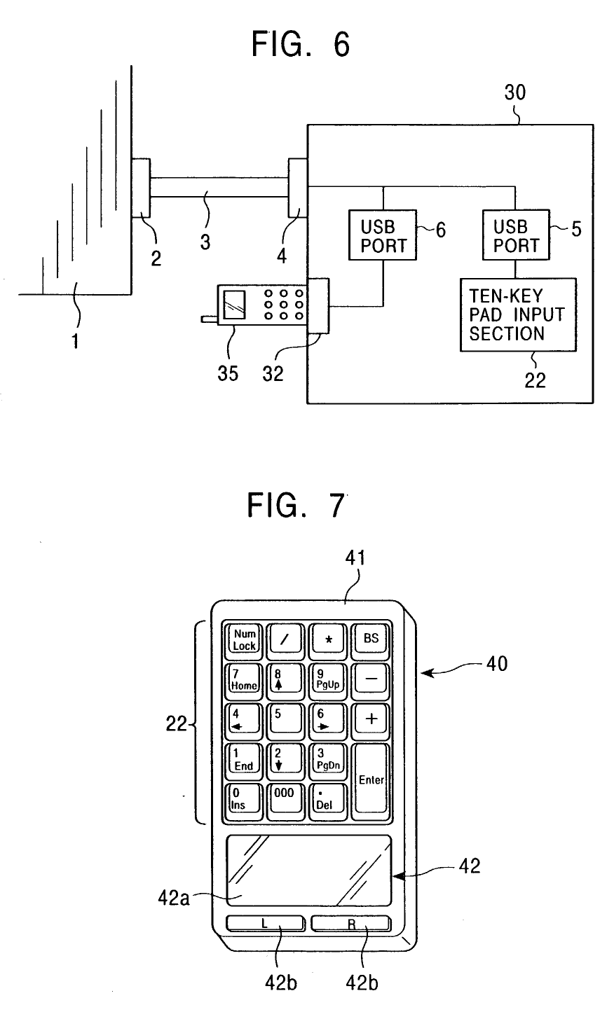

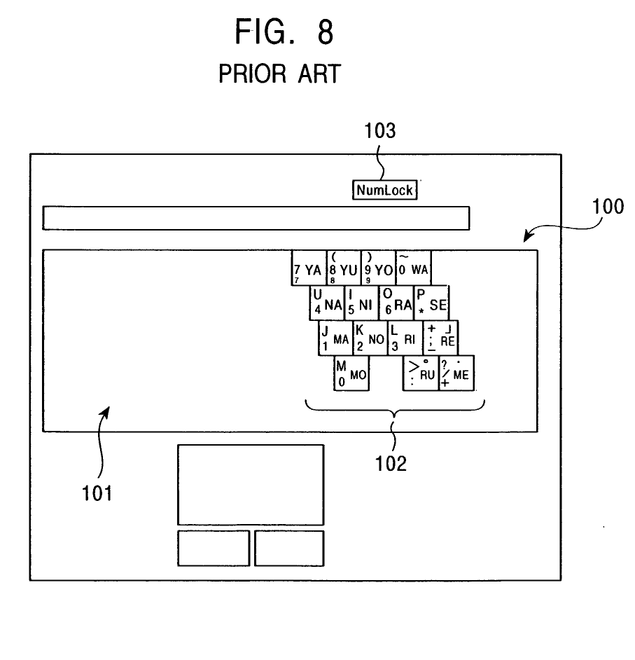

Referring to a block diagram of FIG. 6, the external input unit 30 also has therein the two USB ports 5 and 6 connected to the USB port 4, as in the external input unit 20, to which the third ten-key input section 22 and the connector 32 are connected, respectively. FIG. 6 shows a state in which a mobile telephone 35 is connected to the connector 32. Providing the connector 32 may allow an address book stored in the mobile telephone 35 to be edited with the keyboard unit of the computer main unit 1 or, alternatively, may allow charging of the mobile telephone 35 over the power supply line of the USBs. Also, Japanese characters may be assigned to the ten-keys of the third ten-key input section 22 so that characters generated in the third ten-key input section 22 may be inputted to the mobile telephone 35. The unit that is communicated with the connector 32 may not be the mobile telephone 35, but may be a mobile terminal such as a PDA (personal digital assistant).

The connector mounted to the external input unit 30 may not be connected to the mobile telephone and the PDA, but may be a transmitter-receiver capable of communicating with other external units apart from the external input unit 30, using radio waves or infra-red light, such as Bluetooth and IrDA or, alternatively, may be a transmitter-receiver for a wireless LAN (local area network), or a modem for connecting a mobile telephone and a PDA to a public circuit.

FIG. 7 is a perspective view of an external input unit 40 according to a fourth embodiment of the present invention. The external input unit 40 has a pointing device 42 as a means for entering coordinates in addition to the third ten-key input section 22 in a casing 41. The pointing device 42 includes a pad-type entry member 42a and a push operation switches 42b. The pad-type entry member 42a can be selected from an electrical-capacitance type, a pressure-sensitive type, and a layer of the electrical-capacitance type and the pressure-sensitive type.

For example, an electrical-capacitance entry member 42a is formed of a sheet having an X electrode and a Y electrode made of an Ag-based paste faced in the form of matrix with a resin sheet sandwiched therebetween. The resin sheet is made of PET (polyethylene telephthalate) or the like and has an insulating property and a predetermined dielectric property. When the top sheet is touched with a dielectric substance such as a finger, the electrical capacitance between the X electrode and the Y electrode changes at the contact portion, thus allowing coordinate entry on the X-Y plane.

The pressure-sensitive entry member has a resistive element having difference in potential in the X and Y directions and a conductive element facing thereto. When any portion is pressed, the conductive element and the resistive element are brought into contact with each other to change the resistivity, thereby allowing coordinate entry.

In the external input unit 40, the pointing device having the pad entry member 42a was described as an example; however, it is not limited to that, but a stick-type entry member may be mounted in which the deflection and inclination of the stick are determined for coordinate entry; alternatively, a dial entry member rotatably supported in the casing 41 may be mounted.

The present invention is not limited to the external input units 10 to 40, but may be a unit having a display panel formed of a liquid crystal in addition to the ten-key pad, and also may be an external unit that itself functions as a calculator, in which the display panel functions as a display thereof. Also, the display panel may be capable of displaying data accumulated in the computer main unit 1 in a simplified manner.

The external input unit of the present invention may be equipped with a digital camera capable of taking a still image or a moving image, or may be equipped with a printer (output unit) having a black-and-white or color print function or, alternatively, may be equipped with a USB hub for connecting a plurality of USB-compliant external units. Alternatively, a suitable combination of the display panel, the camera, and the printer may be mounted.

As described using the external input unit 10 of the first embodiment, the external input units of the second to fourth embodiments may also have an arrangement having no [Num Lock] key with a key layout in which keys and characters are assigned one to one. This allows ten-key entry operation at all times and eliminates the need to provide the computer main unit 1 with new software compliant with the external input unit.

The present invention is particularly suitable for use in connection with a laptop computer, and is capable of various entry operations in limited space, and is also capable of numeric entry and cursor key entry as well as Japanese entry without switching the [Num Lock] key as the need arises.

What is claimed is:

1. An external input unit with a ten-key pad connectable to a computer main unit having an integrated or separate key input section, wherein:
a casing separate from the computer main unit includes at least ten-key and cursor-key arrangement; and a circuit in the casing and the computer main unit are connected through a single interface circuit.

2. The external input unit according to claim 1, wherein the casing includes no character entry keys and symbol entry keys.

3. An external input unit with a ten-key pad connectable to a computer main unit having an integrated or separate key input section, wherein:
a casing separate from the computer main unit includes at least ten-key arrangement; the casing further includes a recording-medium drive unit to which a recording medium is mounted; and a circuit in the casing and the computer main unit are connected through a single interface circuit.

4. An external input unit with a ten-key pad connectable to a computer main unit having an integrated or separate key input section, wherein:
a casing separate from the computer main unit includes at least ten-key arrangement; the casing further includes a connector capable of communicating with another external input unit or portable terminal; and a circuit in the casing and the computer main unit are connected through a single interface circuit.

5. An external input unit with a ten-key pad connectable to a computer main unit having an integrated or separate key input section, wherein:
a casing separate from the computer main unit includes at least ten-keys and a coordinate entry means; and a circuit in the casing and the computer main unit are connected through a single interface circuit.

6. The external input unit according to claim 1, wherein the casing includes a display panel.

7. The external input unit according to claim 1, wherein the casing integrally or detachably includes a camera capable of digital input.

8. The external input unit according to claim 1, wherein the casing integrally includes an output means having a print function.

9. The external input unit according to claim 1, wherein the casing includes no [Num Lock] key, and numeric entry with the ten-key pad provided to the casing and character or symbol entry with the key input section of the computer main unit can be performed in parallel.
